(19) United States
(12) Patent Application Publication
(10) Pub. No.: US 2002/0142234 A1
(43) Pub. Date: Oct. 3, 2002

(54) Photomask

(76) Inventors: Gregory A. Hansel, Richfield, MN (US); Chad D. DuBois, Crystal, MN (US); Donald P. Beadles, Chanhassen, MN (US)

Correspondence Address: GRAY, PLANT, MOOTY, MOOTY & BENNETT, P.A., P.O. BOX 2906, MINNEAPOLIS, MN, 55402-0906, US

(21) Appl. No.: 10/112,386

(22) Filed: Mar. 28, 2002

Related U.S. Application Data
(60) Provisional application No. 60/279,897, filed on Mar. 29, 2001.

(51) Int. Cl. G03C 5/00; G03F 9/00

(52) U.S. Cl. 430/5; 430/322; 430/323; 430/324

(57) ABSTRACT

A photomask and a method of making one for use in the photolithographic production of integrated circuits, printed circuit boards, etched metal parts and the like. The photomask has a film layer that is composed of a transparent polymer film prepared with a photolithographic image. In one embodiment the polymer film is emulsion based and the photolithographic image is photographically fixed to the film. The photomask includes a rigid transparent substrate such as a piece of glass of high optical quality. An adhesive bonds the polymer film to the glass. The photomask has qualities of a more expensive chrome-on-glass photomask.

### CROSS REFERENCE TO A RELATED APPLICATION

This application claims the benefit of U.S. Provisional Patent Application Serial No. 60/279,897 filed Mar. 29, 2001 entitled Film Glass Phototool.

### BACKGROUND OF THE INVENTION

A photomask is a master pattern often in the form of a high precision plate used to make lines, circles, contacts and the like on a wide variety of substrates and in a wide variety of applications. Photomasks are necessary in the photolithographic production of a variety of products including printed circuit boards, metal etched parts, television masks and the like. A photomask may be used thousands or millions of times, as in semiconductor production, or used only one or two times as in custom circuit or PCB production.

A photomask is constructed of an opaque material on a carrier. Some common opaque materials are chrome, iron oxide, and silver halide emulsion. The material of the carrier, also called the substrate, is usually glass or plastic. In the construction of the photomask, a pattern is applied to the opaque material according to the application. The pattern can be formed using a photographic process or a direct write laser or sub-masters on a stepper. The opaque material must block particular wave lengths of light, be resistant to scratches and cleaning agents, be repairable if the mask becomes damaged, and bond well to the carrier. The carrier must be transparent to wavelengths of light used during the photolithographic process employing the photomask.

A photomask having a chromium layer deposited on a glass carrier is dimensionally stable, scratch resistant and durable. Blanks for such photomasks are purchased with a photo resist coating over the chrome layer ready for the photomask maker to write a pattern. The chrome layer can be patterned to 1 or 2 microns which, on the proper type of glass, will show very little increase or decrease in size with temperature changes. These are generally the most expensive photomasks. An iron oxide coating on the glass substrate is a little less costly than chrome and has somewhat equivalent resolution limits and dimensional control.

A relatively inexpensive photomask is one manufactured with a photographic emulsion on glass or plastic. This photo mask is used for low resolution patterning applications. It is the most easily damaged of the photomasks in common use. Although inexpensive, the photomask has many disadvantages in that the image layer is mechanically weak, the silver image is opaque to visible light, and the edge acuity is poor due to the grain property of the silver.

### SUMMARY OF THE INVENTION

The present invention is directed to a photomask as well as a method of making a photomask. A photomask according to the invention includes a rigid transparent substrate formed of glass or a glass-like material, and a flexible film layer secured to the surface of the substrate. The substrate material can be a plate of photographic glass (e.g. a silica glass, a soda-lime glass, a potash glass, a lead alkali glass, a barium glass, a borosilicate glass, or the like). The film layer carries the photomask pattern, for example a microscopic image of an electronic circuit. The film layer can be a photographic film with an emulsion coating on one side. The image on the film layer is produced using known film printing and/or photographic technologies.

In terms of a method a film is prepared with a patterned image according to the application. The film is acclimated, cleaned and coated on the emulsion side with a protective coating. The glass substrate is prepared by cleaning as may be necessary, and inspected for scratches, any residual emulsions and other contamination. An optically clear adhesive sheet is laminated to one side of the substrate. The back of the imaged film is cleaned. The backing is peeled away from the adhesive sheet exposing the adhesive layer. The imaged film is laminated to the substrate on the adhesive layer. Excess adhesive sheet and film is trimmed away. The bond is cured.

The resultant photomask is one that has optical properties comparable to an expensive chrome on glass photomask at much less cost.

### IN THE DRAWINGS

FIG. 1 is a perspective view of a photomask according to the present invention;

FIG. 2 is an enlarged view of a portion of the photomask of FIG. 1 with portions broken away for purposes of illustration;

FIG. 3 is an assembly view illustrating the method according to the invention of making a photomask; and

FIG. 4 is a schematic flow diagram of the method according to the invention of making a photomask.

### DESCRIPTION OF A PREFERRED EMBODIMENT

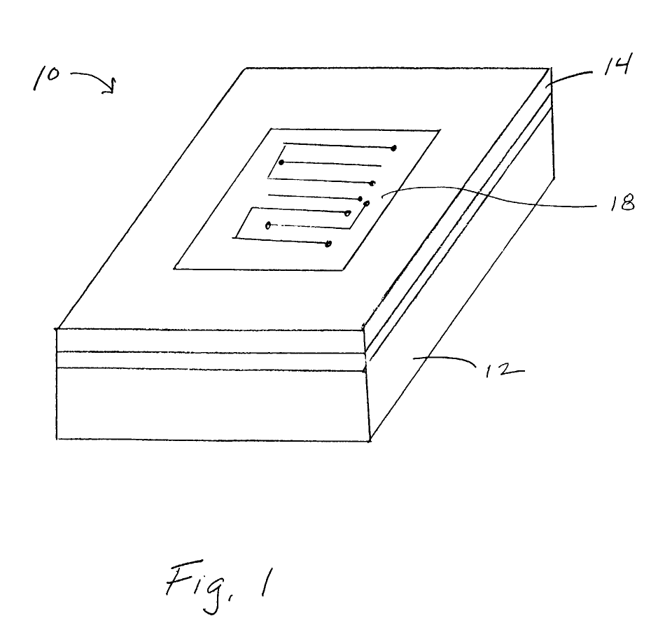

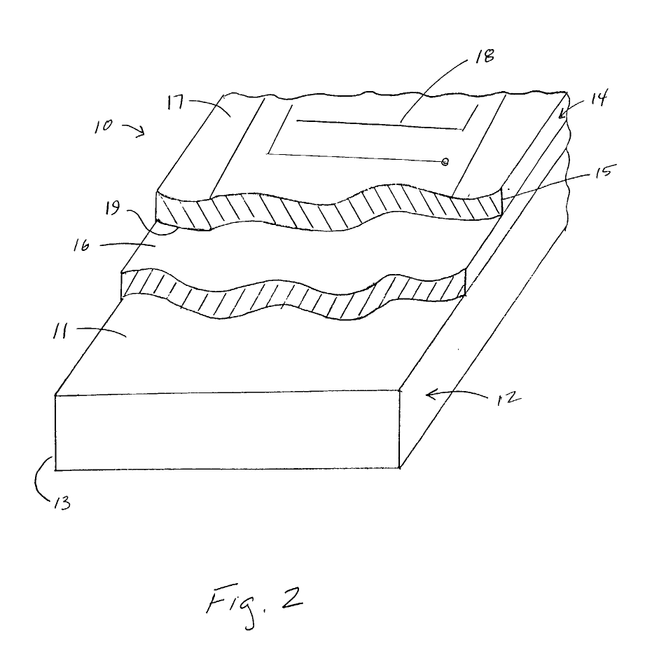

Referring to the drawings there is shown in FIG. 1 and with portions removed in FIG. 2, a photomask according to the invention indicated generally at 10. Photomask 10 includes a hard transparent substrate 12 and a flexible film layer 14. Substrate 12 is a rigid dimensionally stable plate or film which in a preferred embodiment is formed of a glass such as silica glass, soda-lime glass, potash glass, lead alkali glass, barium glass, borosilicate glass; or a transparent plate or film of natural or synthetic material such as ruby, quartz, sapphire, beryl or the like; or a transparent synthetic resin plate or film such as polymethyl methacrylate, polyethylene terephthalate, polycarbonate, polystyrene, polyethylene, polypropylene, etc. The substrate 12 will generally but not necessarily be flat and in a plate like form with sufficient structural integrity to function as a photomask support. Substrate 12 has a thickness 13 that is suitable for photomask support, generally about 0.5 to 3 mm. Substrate 12 has a front face 11 for receipt of a patterned film layer.

The film layer is patterned with an image 18 suitable for use in a photolithographic process. Photolithographic image 18 can, for example, represent an electrical circuit. In the embodiment shown film layer 14 is an emulsion based product which receives image 18 through a photographic process. An example is a Mylar® photographic emulsion based product. Film layer is preferably a thin polymeric film such as 7 mil light sensitive Mylar® film. Film layer 14 is clear or transparent apart from the image 18. Film layer 14 can be patterned by other than photographic processes, including other optical, mechanical, electrical and chemical techniques or computer performed algorithms.

Film layer 14 is adhered to the substrate 12 by an adhesive layer 16 (shown exaggerated in the drawings for purposes of illustration). Adhesive layer 16 is formed of any suitable clear or transparent adhesive substance that will not react with either film layer 14 or substrate 12.

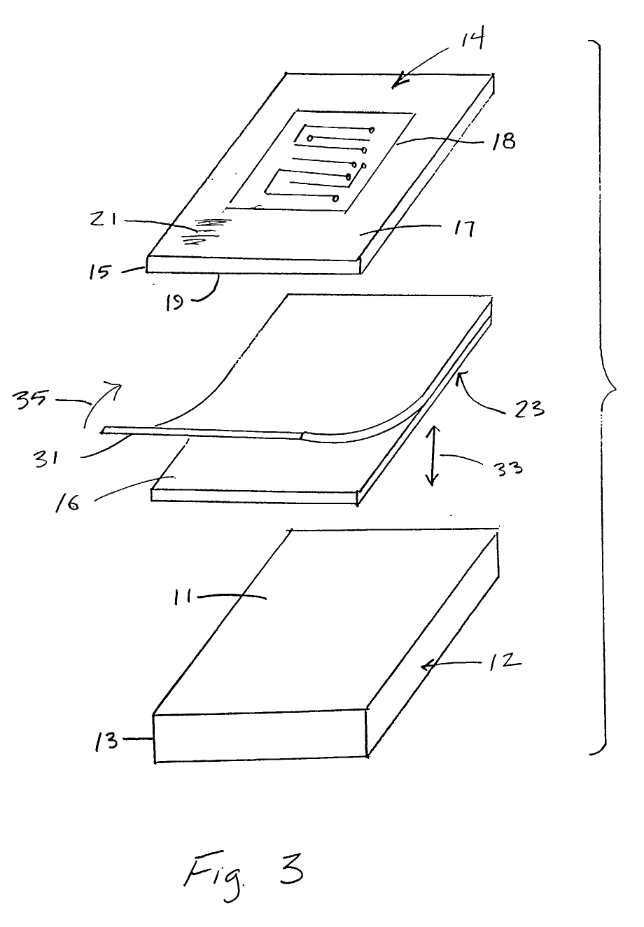

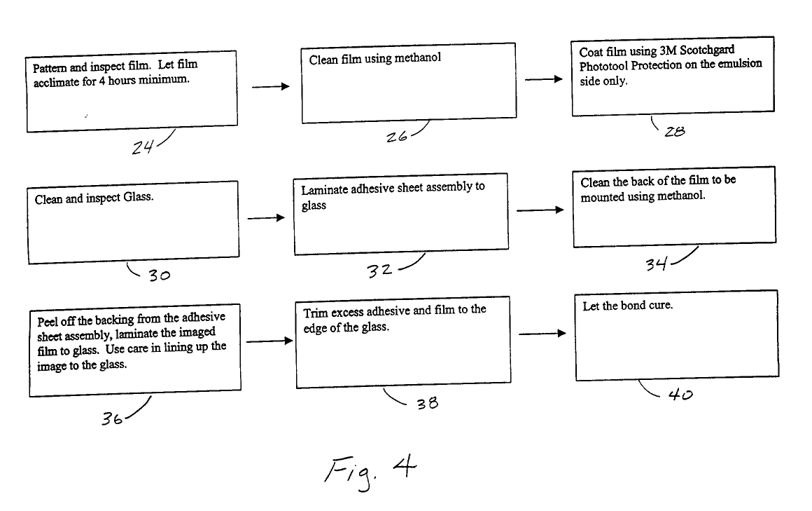

A method of making a photomask according to the invention is shown in the assembly view of FIG. 3 and illustrated by the flow diagram of FIG. 4. A sheet of polymer film such as Mylar® has a base side 19 and a coating side 17 prepared with a photographic emulsion coating. A photomask pattern 18 is applied to the coating side 17 through conventional photographic methods to fabricate the film layer. The film layer is permitted to acclimate for a period of 4 to 12 hours (indicated at 24 in FIG. 4). This can be accomplished in a conditioning cabinet where the film layer can acclimate to ambient temperature and humidity. Next the film is cleaned using methanol or an equivalent material (26 in FIG. 4). The film is coated on the emulsion side 17 with a suitable protective coating (indicated at 21 in FIG. 3) in order to seal it from the effects of humidity (28 in FIG. 4). A suitable material for this task is 3M Scotchguard Protection Film Protector II. The next step (30 in FIG. 4) is to inspect and clean the substrate, which will generally be glass. If an emulsion coated glass is being recycled, the glass must be completely stripped of the emulsion with a suitable reagent such as household bleach. The inspection should detect scratches, dust, remaining emulsion and other contaminates.

The next step (32 in FIG. 4) involves the use of an adhesive sheet assembly of the type having an adhesive sheet covered with protective backing sheets. Such a product is 3M Optically Clear Laminating Adhesive which has backing on both sides of an adhesive sheet. A sheet is cut to a size larger than the surface dimensions of the front surface 11 of the glass substrate. The backing is removed from one side of the adhesive sheet assembly. A laminating machine is used to laminate the adhesive sheet assembly to the front surface of the substrate using approximately 30 pounds per square inch pressure (indicated by the arrow 33 in FIG. 3). Alternatively, the glass substrate surface 11 is prepared with a fine mist of a slip agent and the adhesive is carefully placed on the slip agent. A squeegee or like device is used to remove excess water or air or both from between the substrate surface and the adhesive sheet. The adhesive sheet is trimmed and allowed to cure for a suitable period of time such as 24 hours.

Next the back of the film layer, or the side opposite the emulsion, is cleaned with methanol (34). The backing sheet 31 (FIG. 3) of the adhesive sheet assembly 23 is peeled away and, with the use of a laminating machine, the newly exposed surface of the adhesive sheet is laminated to the film layer (36 in FIG. 4). Care is taken to line up the image 18 to the substrate 12. In lieu of the laminating process the procedure described above can be followed.

The following step is to trim the excess adhesive strip (if any) and film layer to the edge of the glass (38). The next step is let the bond cure for a suitable period of time, for example, 24 to 48 hours (40).

The result is a photomask having resolution characteristics comparable to a chrome-on-glass photomask but manufactured at considerably less cost.

The embodiments of the invention in which an exclusive property or privilege is claimed are defined as follows:

1. A photomask for use in photolithography comprising:
a rigid transparent substrate layer with a front surface;
a flexible transparent polymer film layer;
a photolithographic image fixed to the film;
an adhesive layer attaching the polymer film to the front surface of the substrate.

2. The photomask of claim 1 wherein:
said substrate is a glass plate.

3. The photomask of claim 2 wherein:
the substrate is formed of a glass chosen from the group consisting of: silica glass; soda-lime glass; potash glass; lead alkali glass; barium glass; and borosilicate glass.

4. The photomask of claim 1 wherein:
said substrate is a transparent plate formed of a natural material chosen from the group consisting of: ruby; quartz; sapphire; beryl.

5. The photomask of claim 1 wherein:
the substrate is a transparent plate of synthetic resin material.

6. The photomask of claim 5 wherein:
the synthetic resin material is chosen from the group consisting of: polymethyl methacrylate; polyethylene terephthalate; polycarbonate; polystyrene; polyethylene; polypropylene.

7. The photomask of claim 1 wherein:
the film layer is an emulsion based product;
said image fixed to the film layer through a photographic process.

8. The photomask of claim 1 wherein:
the image is fixed to the film layer by a photographic process.

9. The photomask of claim 1 wherein:
the image is fixed to the film layer by a mechanical process.

10. The photomask of clam 1 wherein:
the image is fixed to the film layer by a chemical process.

11. The photomask of claim 1 wherein:
the image is fixed to the film layer by a computer process.

12. A method of making a photomask comprising the steps of:
a. providing an emulsion based polymer film and photographically fixing a photolithographic image to the emulsion side of the film;
b. acclimating the film for a period of time as may be necessary;
c. cleaning the film;
d. coating the emulsion side of the film with a protective coating;
e. providing a clean and inspected glass substrate;
f. securing an adhesive sheet assembly having a transparent adhesive to one side of the substrate;
g. cleaning the back of the film opposite the emulsion side;
h. bonding the back side of the film to the adhesive sheet assembly;
i. allowing the bond to cure.
